(19) United States
(12) Patent Application Publication
(10) Pub. No.: US 2005/0281959 A1
(43) Pub. Date: Dec. 22, 2005

(54) Plasma generating apparatus and method of forming alignment film of liquid crystal display using the same

(76) Inventor: Seok Kyun Song, Seoul (KR)

Correspondence Address: PARK & SUTTON LLP, 3255 WILSHIRE BLVD, SUITE 1110, LOS ANGELES, CA, 90010, US

(21) Appl. No.: 11/080,232

(22) Filed: Mar. 15, 2005

(30) Foreign Application Priority Data
Jun. 16, 2004 (KR) 10-2004-0044688

(51) Int. Cl. C23C 16/00

(52) U.S. Cl. 427/569; 118/723 E; 427/58; 427/162

(57) ABSTRACT

The present invention relates to a plasma generating apparatus and a method of forming an alignment film of a liquid crystal display using the plasma generating apparatus. A high voltage is applied to the main electrode to generate a high non-regular electric field having directivity. Thus, the main electrode generates plasma of a high density having directivity. In this time, plasma is oriented toward a substrate at a proper angle and generates plasma having directivity. Large-area low temperature plasma can be generated through a simple structure, and a flat panel and roll to roll 3-D sample processing condition can be satisfied. Thus, surface reforming and cleaning of any material such as metal, semiconductor, plastic and ceramics regardless of the type of a sample can be easily made. It is thus possible to effectively form an alignment film of a liquid crystal display using this plasma generating apparatus.

### CROSS-REFERENCE TO RELATED APPLICATION

This application claims benefit under 35 U.S.C. § 119 from Korean Patent Application No. 10-2004-0044688, filed on Jun. 16, 2004, the entire content of which is incorporated herein by reference. A related application is Korean Patent Application No. 10-2003-0065599, filed on Sep. 22, 2003, and the content of which is incorporated herein by reference.

### BACKGROUND OF THE INVENTION

1. Field of the Invention

The present invention relates to a plasma generating apparatus and a method of forming an alignment film of a liquid crystal display using the plasma generating apparatus. More particularly, the present invention relates to a plasma generating apparatus having a structure in which a main electrode having a magnet which can generate a high non-uniform electric field is disposed within a magnetic field having constant directivity and the main electrode is applied with a high voltage to generate plasma having directivity.

Further, the present invention relates to a plasma generating apparatus in which plasma of a high density and directivity can be provided and a plasma generating length can increase, in such a manner that in order to improve the plasma density of the main electrode, a first electrode is disposed in a plasma apparatus having the main electrode whereby plasma provided additionally is generated around the main electrode, and ions, electrons and an active gas are thus supplied to the main electrode.

In addition, the present invention relates to a plasma generating apparatus in which proper current limiting power is connected to electrode structure pair of curvature structure shape, which face each other, and the direction and flow rate of a working gas are controlled to generate plasma of various sizes and kinds.

Also, the present invention relates to polyimide surface processing and diamond like carbon (DLC) thin film fabricating technologies for a method of forming an alignment film of a liquid crystal display using a plasma generating apparatus.

2. Background of the Related Art

Generally, plasma is a fourth material state and is composed of ions, electrons, radicals, etc., which are generated by an electric field that is applied from the outside, etc. and neutron particles. Plasma has a material state that is electrically neutral macroscopically. Ions, electrons, radicals, etc. within this plasma have been widely used in various fields including surface reforming, etching, coating, sterilization, disinfection, generation of ozone, dyeing, purification of wastewater and city water, air purification, a high brightness lamp and the like.

This plasma can be classified into low pressure (several mm Torr to several Torr) plasma and high pressure (several Torr to 760 Torr) plasma depending upon a pressure generated.

Of them, the low pressure plasma can be easily generated, but requires an expensive vacuum chamber, an expensive exhaust apparatus, etc. for maintaining a low pressure state. Further, the low pressure plasma has a limit to mass processing due to a product input mode of a batch type. On the contrary, the atmospheric pressure plasma has advantages that it does not need an expensive vacuum system since plasma is generated in an atmospheric pressure (760 Torr) state and it is suitable for mass production because a consecutive process is possible.

Meanwhile, the performance of a liquid crystal display (LCD) is largely dependent upon the properties of an alignment film. That is, resolution of the LCD significantly depends upon how well liquid crystal is aligned on the alignment film.

Currently, the alignment film of the LCD is fabricated by coating polyimide in an expensive clean room, curing polyimide at a high temperature of 200° C. and rubbing the surface of polyimide using a roller for alignment.

The above-mentioned method has disadvantages that cost increases and a manufacturing time lengthens due to the use of the clean room and high temperature. Further, the rubbing process using the roller has significant problems. That is, there are problems in that the roller is degraded due to mechanical rubbing, scraps such as small fragments are generated, the scraps cause local defects, and these defects cannot be confirmed even after several hundreds of processes are preformed.

The rubbing process can give damage to electrical circuits such as a thin film transistor (TFT) due to generation of static electricity by rubbing and can degrade the quality of an image due to stripe rubbing marks. In addition, there is a problem in that washing and dry processes must be carried out after the rubbing process. Incidentally, there is a problem in that contrast is not uniform due to weak alignment by shadowed areas by spacer balls or posts during the rubbing process.

Many Research groups have conducted researches on non-contact alignment film formation technology. Also, researches on a LB method, a Grating method, MOLCA (Magnetically Oriented Liquid Crystalline Adsobate magnetic field application surface adsorption method, an optical alignment method, etc. have been made. However, these methods have not been commercialized yet due to their native disadvantages.

In recent years, IBM Corp. developed LCD alignment technology by a non-contact type ion beam and released a LCD having resolving power of 3,840×2,400 (approximately 9.2 million) pixels in 22 inches of two-domain having the highest resolution, which was impossible by existing rubbing method. (J. Stohr, M. G. Samant, J. Luning, A. C. Callegari, P. Chaudhari, J. P. Doyle, J. A. Lacey, S. A. Lien, S. Purushothaman, J. L. Speidell, “Liquid crystal alignment on carbonaceous surfaces with orientational order”, SCIENCE V. 292, p. 2299-2302, Jun. 22, 2001), (P. Chaudhari, J. A. Lacey, S. A. Lien, “Method an apparatus for forming an alignment pattern on a surface using a particle beam useful for a liquid crystal”, U.S. Pat. No. 6,124,914 (Sep. 26, 2000)), (P. Chaudhari, E. A. Galligan, J. P. Doyle, J. A. Lacey, S. A. Lien, H. Nakano, M. Lu, “Method for making a liquid crystal alignment layer”, U.S. Pat. No. 6,331,381 (Dec. 18, 2001)), (P. Chaudhari, J. A. Lacey, S. A. Lien, “Liquid crystal display having alignment layer using ion bombarded amorphous material 100 Å thickness or less”, U.S. Pat. No. 6,346,975 (Feb. 12, 2002)), Alignment by the ion beam can not only solve the aforementioned problems, but also significantly reduce the failure rate and thus lower the unit cost.

However, the method by the ion beam, which was disclosed by IBM Corp., has disadvantages that it requires expensive ion source apparatus and vacuum apparatus since a large-area ion source is used, process is discontinuous because of the type of alignment, etc. In manufacturing a LCD, the size of a glass substrate gradually increases for purposes of the size of a monitor and productivity. The ion beam process by IBM Corp. requires an ion beam source of a large processing width. As the amount of the ion source increases, prices increase in an arithmetical progression. However, an atmospheric pressure plasma apparatus of the present invention has advantages that it can be easily made large and it is cost effective. Moreover, an ion source must be specially managed and maintained. However, the atmospheric pressure plasma of the present invention can be managed and maintained easily.

A dielectric barrier type (T, Yokoyama, M. Kogoma, T. Moriwaki, and S. Okazaki, J. Phys. D: Appl. Phys. V23, p 1125 (1990)), (John R. Roth, Peter P. Tsai, Chaoyu Lin, Mouuir Laroussi, Paul D. Spence, “Steady-state, Glow discharge plasma”, U.S. Pat. No. 5,387,842 (Feb. 7, 1995), “One Atmosphere, Uniform Glow discharge plasma”, U.S. Pat. No. 5,414,324 (May 9, 1995)) has been most commonly used as a method of generating plasma while prohibiting arc discharging in an atmospheric pressure. Further, a resistant type (Yu. S. Akishev, A. A. Deryugin, I. V. Kochetov, A. P. Napartovich, and N. I. Trushkin, J. Phys. D: Appl. Phys. V26, p 1630 (1993)), a perforated dielectric type, a capillary type (Erich E. Kunhardt, Kurt H. Becker, “Glow plasma discharge device having electrode covered with perforated dielectric”, U.S. Pat. No. 5,872,426 (Feb. 16, 1999)) or the like can be also used.

An AC barrier type method using a flat panel dielectric is a method in which a ceramic dielectric material such as alumina, etc. that prohibits arc discharging is inserted into both sides or one side of upper and lower electrodes having a predetermined electrode gap and a high AC or DC pulse voltage is applied to the ceramic dielectric to generate atmospheric pressure plasma. In this method, however, a predetermined thickness that does not cause dielectric breakage should be kept and a low plasma density is inevitably obtained due to current prohibition by the dielectric of the thickness. In the dielectric method, a high peak current is used since a generated plasma time is very short. Thus, there is a disadvantage in that a power supply unit that can provide power very higher than an actual power must be used.

Further, the dielectric method has a disadvantage that it is weak to heat because ceramics, etc. are used as the dielectric material. In addition, it has disadvantages that energy efficiency is low because lots of energy is lost as heat due to wall charge on the dielectric material. Also, uniformity of plasma is degraded because streamer plasma is generated.

The dielectric barrier type of the upper and lower electrodes is not suitable for processing samples of a three-dimensional structure because the length of plasma generated is limited to between the electrodes and its length is not long. A plasma torch, a plasma shower, etc. are suitable for processing samples of a three-dimensional structure, etc., but things that have been developed so far are mostly for arc plasma. Thus, they have a small plasma generating area and limited applications due to thermal plasma.

Meanwhile, in order to form the alignment film of the LCD, it is required that plasma or ions have motion energy in a predetermined direction and energy of directivity having a given angle to a substrate be transferred to the surface of the alignment film so that surface reforming occurs. Atmospheric pressure plasma that has been developed so far does not secure surface processing directivity by plasma. Also, atmospheric pressure plasma for large-area 3-D processing has not yet been reported.

A plasma shower type (Y. Sawada, K. Nakamura, H. Kitamura, Y. Inoue, “Plasma treatment apparatus and plasma treatment method performed by use of the same apparatus”, U.S. Pat. No. 6,424,091 (Jul. 23, 2002)) by a dielectric barrier, which has recently been disclosed, corresponds to a low temperature plasma shower type that can be made large with corona or glow discharging not high temperature plasma of arc. However, the plasma shower type has problems that it cannot form the alignment film of the LCD since there is no directivity of plasma and it is difficult to process samples of a 3-D structure because a distance between electrodes is very short and the length of plasma generated is small, several mm.

Atmospheric pressure plasma conditions for forming the LCD alignment film may include directivity of plasma having a given tilt angle in surface processing and a large-area processing capability. However, this type of an atmospheric pressure plasma generating apparatus has not yet been reported.

In the case of a LCD used in a projector, a projection television or the like, an organic polyimide alignment film is severely degraded since high heat is generated in the LCD due to illumination of strong light. Thus, there are problems in that polymer chains are broken, the life span is shortened, an afterimage is generated because generation of remaining charges increases and the like.

Therefore, due to the above problems and the necessity of stability, etc. in a high temperature process in a post-process, technology for forming an inorganic alignment film has been researched. (T. Shimada, M. Asami, H. Natsuhori, S. Shimizu, T. Konno, “Liquid crystal display device with homeotropic alignment layer underciat formed by ion beam assisted vapor deposition of oxide gas”, U.S. Pat. No. 5,268,781 (Dec. 7, 1993)) Although various oxide thin films, etc. have been researched as the inorganic alignment film, they have not been commercialized due to a difficulty in uniform deposition of a level required in a large-area tilt angle, a difficulty in securing properties of a desired level, etc.

A DLC (Diamond Like Carbon) thin film as the inorganic alignment film is suitable for the LCD alignment film because a relatively uniform thin film can be obtained in a large area. The DLC thin film has been widely used in the fields of hard disk protection film coating in most computers, mechanical tool hard coating, etc. Technology for forming the DLC thin film may include PECVD, sputtering, ion beam and the like. (F. D. Bailey, et al., “Diamond-Like Carbon films from a hydrocarbon helium plasma”, U.S. Pat. No. 5,569,501 (Oct. 29, 1996)), (F. D. Bailey, et al., “Diamond-Like Carbon films from a hydrocarbon helium plasma”, U.S. Pat. No. 5,470,661 (Nov. 28, 1995)), (E. D. Babich, et al., “Sputter deposition of hydrogenated amorphous carbon film and applications thereof”, U.S. Pat. No. 5,830,332 (Nov. 3, 1998))

Technology for forming a DLC alignment film that has been recently released by IBM Corp. includes forming a DLC thin film in two-step process and illuminating an ion beam to the DLC thin film with argon ion of several hundred eV energy at a given tilt angle, thereby forming an alignment film.

### SUMMARY OF THE INVENTION

According to the present invention, the aforementioned two-step process can be simplified into a 1-step process in such a manner that an alignment film and a DLC thin film are formed at the same time through atmospheric pressure plasma. The present invention relates to technology in which a DLC alignment film can be easily formed by supplying a gas in which H₂ and Ar gas are mixed with C₂H₂ or CH₄ gas to an atmospheric pressure plasma apparatus of the present invention.

According to a first aspect of the present invention, there is provided a plasma generating apparatus that generates a main plasma using a discharge phenomenon that is caused by a high non-uniform electric field in a main electrode by a voltage supplied between a ground electrode and the main electrode from a power supply unit and a working gas, including discharge electrodes that are spaced apart by a certain distance from the side of the main electrode that is applied with the voltage to generate the main plasma; at least one blade electrode disposed beneath the bottom of the main electrode; and a magnet located at the back of the blade electrodes, for generating a magnetic field that gives directivity to the generated main plasma, wherein a predetermined power supply unit supplies power to the main electrode and the discharge electrodes, and the working gas is supplied between the main electrode and the discharge electrodes to thereby generate discharge plasma preferentially.

According to a second aspect of the present invention, there is provided a plasma generating apparatus, including a dielectric upper electrode of a rod shape; a first magnet disposed over the dielectric upper electrode; a substrate disposed below the dielectric upper electrode; a dielectric lower electrode of a rod shape that is disposed below the substrate; and a second magnet disposed under the dielectric lower electrode, wherein a predetermined power supply unit applies power between the upper and lower electrodes of the rod shape to generate plasma.

According to a third aspect of the present invention, there is provided a plasma generating apparatus that uses a working gas to generate plasma, including a metal electrode of a sheet shape that is powered by a power supply unit; a sample located on the metal electrode; an upper magnet that is located over the sample at a distance of over an average free path length of electrons and forms the direction of a magnetic field oriented toward the sample at a constant tilt angle; and a lower magnet located below the metal electrode so that the lower magnet has the same magnetic field direction as the upper magnet, wherein the lower magnet is connected to the power supply unit connected to the metal electrode, whereby the lower magnet is powered by the power supply unit to generate plasma.

According to a fourth aspect of the present invention, there is provided a method of forming an alignment film of a liquid crystal display, including a first step of preparing a plasma generating apparatus that generates a main plasma using a discharge phenomenon that is caused by a high non-uniform electric field at a main electrode by a voltage supplied between a ground electrode and the main electrode from a power supply unit and a working gas wherein discharge electrodes are spaced apart by a certain distance from the side of the main electrode, a voltage is supplied to the main electrode and the discharge electrodes and the working gas is supplied between the main electrode and the discharge electrodes to generate discharge plasma, at least one blade electrode is disposed beneath the main electrode, and a magnet is located at the back of the blade electrode to generate a magnetic field that gives directivity to the main plasma; a second step of forming a thin film transistor on the substrate; a third step of forming an ITO electrode on the thin film transistor; a fourth step of forming a polyimide film on the ITO electrode; and a fifth step of processing the surface of the polyimide film of the substrate using the plasma generated by the plasma generating apparatus.

According to a fifth aspect of the present invention, there is provided a method of forming an alignment film of a liquid crystal display, including a first step of preparing a plasma generating apparatus, wherein the plasma generating apparatus includes a dielectric upper electrode of a rod shape, a first magnet disposed over the dielectric upper electrode, a substrate disposed below the dielectric upper electrode, a dielectric lower electrode of a rod shape that is disposed below the substrate, and a second magnet disposed under the dielectric lower electrode, wherein a predetermined power supply unit applies power between the upper and lower electrodes of the rod shape to generate plasma; a second step of forming a thin film transistor on the substrate; a third step of forming an ITO electrode on the thin film transistor; a fourth step of forming a polyimide film on the ITO electrode; and a fifth step of providing the substrate in which the polyimide film is formed to the plasma generating apparatus that is prepared in the first step, and processing the surface of the polyimide film of the substrate using the plasma generated by the plasma generating apparatus.

According to a sixth aspect of the present invention, there is provided a method of forming an alignment film of a liquid crystal display, including a first step of preparing a plasma generating apparatus that uses a working gas to generate plasma, wherein the plasma generating apparatus includes a metal electrode of a sheet shape that is powered by a power supply unit, a substrate located on the metal electrode, an upper magnet that is located on the substrate at a distance of over an average free path length of electrons and forms the direction of a magnetic field oriented toward the substrate at a constant tilt angle, and a lower magnet located below the metal electrode so that the lower magnet has the same magnetic field direction as the upper magnet, wherein the lower magnet is connected to the power supply unit connected to the metal electrode, whereby the lower magnet is powered by the power supply unit to generate plasma; a second step of forming a thin film transistor on the substrate; a third step of forming an ITO electrode on the thin film transistor; a fourth step of forming a polyimide film on the ITO electrode; and a fifth step of providing the substrate in which the polyimide film is formed to the plasma generating apparatus that is prepared in the first step, and processing the surface of the polyimide film of the substrate using the plasma generated by the plasma generating apparatus.

According to a seventh aspect of the present invention, there is provided a method of forming an alignment film of a liquid crystal display, including a first step of preparing a plasma generating apparatus that generates a main plasma using a discharge phenomenon that is caused by a high non-uniform electric field at a main electrode by a voltage supplied between a ground electrode and the main electrode from a power supply unit and a working gas wherein discharge electrodes are spaced apart by a certain distance from the side of the main electrode, a voltage is supplied to the main electrode and the discharge electrodes and the working gas is supplied between the main electrode and the discharge electrodes to generate discharge plasma, at least one blade electrode is disposed beneath the main electrode, and a magnet is located at the back of the blade electrode to generate a magnetic field that gives directivity to the main plasma; a second step of forming a thin film transistor on the substrate; a third step of forming an ITO electrode on the thin film transistor; a fourth step of forming a DLC thin film on the ITO electrode; and a fifth step of providing the substrate in which the DLC thin film is formed to the plasma generating apparatus that is prepared in the first step, and processing the surface of the DLC thin film of the substrate using the plasma generated by the plasma generating apparatus.

According to an eighth aspect of the present invention, there is provided a method of forming an alignment film of a liquid crystal display, including a first step of preparing a plasma generating apparatus, wherein the plasma generating apparatus includes a dielectric upper electrode of a rod shape, a first magnet disposed over the dielectric upper electrode, a substrate disposed below the dielectric upper electrode, a dielectric lower electrode of a rod shape that is disposed below the substrate, and a second magnet disposed under the dielectric lower electrode, wherein a predetermined power supply unit applies power between the upper and lower electrodes of the rod shape to generate plasma; a second step of forming a thin film transistor on the substrate; a third step of forming a DLC thin film on the thin film transistor; and a fifth step of providing the substrate in which the DLC thin film is formed to the plasma generating apparatus that is prepared in the first step, and processing the surface of the DLC thin film of the substrate using the plasma generated by the plasma generating apparatus.

According to a ninth aspect of the present invention, there is provided a method of forming an alignment film of a liquid crystal display, including a first step of preparing a plasma generating apparatus that uses a working gas to generate plasma, wherein the plasma generating apparatus includes a metal electrode of a sheet shape that is powered by a power supply unit, a substrate located on the metal electrode, an upper magnet that is located on the substrate at a distance of over an average free path length of electrons and forms the direction of a magnetic field oriented toward the substrate at a constant tilt angle, and a lower magnet located below the metal electrode so that the lower magnet has the same magnetic field direction as the upper magnet, wherein the lower magnet is connected to the power supply unit connected to the metal electrode, whereby the lower magnet is powered by the power supply unit to generate plasma; a second step of forming a thin film transistor on the substrate; a third step of forming a DLC thin film on the thin film transistor; and a fifth step of providing the substrate in which the DLC thin film is formed to the plasma generating apparatus that is prepared in the first step, and processing the surface of the DLC thin film of the substrate using the plasma generated by the plasma generating apparatus.

According to a tenth aspect of the present invention, there is provided a method of forming an alignment film of a liquid crystal display, including a first step of preparing a plasma generating apparatus that generates a main plasma using a discharge phenomenon that is caused by a high non-uniform electric field at a main electrode by a voltage supplied between a ground electrode and the main electrode from a power supply unit and a working gas wherein discharge electrodes are spaced apart by a certain distance from the side of the main electrode, a voltage is supplied to the main electrode and the discharge electrodes and the working gas is supplied between the main electrode and the discharge electrodes to generate discharge plasma, at least one blade electrode is disposed beneath the main electrode, and a magnet is located at the back of the blade electrode to generate a magnetic field that gives directivity to the main plasma; a second step of forming a thin film transistor on the substrate; a third step of forming an ITO electrode on the thin film transistor; and a fourth step of providing the substrate in which the ITO electrode is formed to the plasma generating apparatus that is prepared in the first step, and processing the surface of the ITO thin film of the substrate using the plasma generated by the plasma generating apparatus.

According to an eleventh aspect of the present invention, there is provided a method of forming an alignment film of a liquid crystal display, including a first step of preparing a plasma generating apparatus, wherein the plasma generating apparatus includes a dielectric upper electrode of a rod shape, a first magnet disposed over the dielectric upper electrode, a substrate disposed below the dielectric upper electrode, a dielectric lower electrode of a rod shape that is disposed below the substrate, and a second magnet disposed under the dielectric lower electrode, wherein a predetermined power supply unit applies power between the upper and lower electrodes of the rod shape to generate plasma; a second step of forming a thin film transistor on the substrate; a third step of forming a DLC thin film on the thin film transistor; and a fourth step of providing the substrate in which the ITO electrode is formed to the plasma generating apparatus that is prepared in the first step, and processing the surface of the ITO thin film of the substrate using the plasma generated by the plasma generating apparatus.

According to a twelfth aspect of the present invention, there is provided a method of forming an alignment film of a liquid crystal display, including a first step of preparing a plasma generating apparatus that uses a working gas to generate plasma, wherein the plasma generating apparatus includes a metal electrode of a sheet shape that is powered by a power supply unit, a substrate located on the metal electrode, an upper magnet that is located on the substrate at a distance of over an average free path length of electrons and forms the direction of a magnetic field oriented toward the substrate at a constant tilt angle, and a lower magnet located below the metal electrode so that the lower magnet has the same magnetic field direction as the upper magnet, wherein the lower magnet is connected to the power supply unit connected to the metal electrode, whereby the lower magnet is powered by the power supply unit to generate plasma; a second step of forming a thin film transistor on the substrate; a third step of forming a DLC thin film on the thin film transistor; and a fourth step of providing the substrate in which the ITO electrode is formed to the plasma generating apparatus that is prepared in the first step, and processing the surface of the ITO thin film of the substrate using the plasma generated by the plasma generating apparatus.

According to a thirteenth aspect of the present invention, there is provided a method of forming an alignment film of a liquid crystal display, including a first step of preparing a plasma generating apparatus that generates a main plasma using a discharge phenomenon that is caused by a high non-uniform electric field at a main electrode by a voltage supplied between a ground electrode and the main electrode from a power supply unit and a working gas wherein discharge electrodes are spaced apart by a certain distance from the side of the main electrode, a voltage is supplied to the main electrode and the discharge electrodes and the working gas is supplied between the main electrode and the discharge electrodes to generate discharge plasma, at least one blade electrode is disposed beneath the main electrode, and a magnet is located at the back of the blade electrode to generate a magnetic field that gives directivity to the main plasma; a second step of forming a thin film transistor on the substrate; a third step of forming an ITO electrode on the thin film transistor; and a fourth step of providing the substrate in which the ITO electrode is formed to the plasma generating apparatus that is prepared in the first step, supplying a gas in which H₂ and Ar gas are mixed with C₂H₂ or CH₄ gas to the plasma generating apparatus, and locating the substrate at a given angle between 0 to 90° to form a DLC thin film on the substrate, thereby directly forming a DLC liquid crystal alignment film.

According to a fourteenth aspect of the present invention, there is provided a method of forming an alignment film of a liquid crystal display, including a first step of preparing a plasma generating apparatus, wherein the plasma generating apparatus includes a dielectric upper electrode of a rod shape, a first magnet disposed over the dielectric upper electrode, a substrate disposed below the dielectric upper electrode, a dielectric lower electrode of a rod shape that is disposed below the substrate, and a second magnet disposed under the dielectric lower electrode, wherein a predetermined power supply unit applies power between the upper and lower electrodes of the rod shape to generate plasma; a second step of forming a thin film transistor on the substrate; a third step of forming a DLC thin film on the thin film transistor; and a fourth step of providing the substrate in which the ITO electrode is formed to the plasma generating apparatus that is prepared in the first step, supplying a gas in which H₂ and Ar gas are mixed with C₂H₂ or CH₄ gas to the plasma generating apparatus, and locating the substrate at a given angle between 0 to 90° to form a DLC thin film on the substrate, thereby directly forming a DLC liquid crystal alignment film.

According to a fifteenth aspect of the present invention, there is provided a method of forming an alignment film of a liquid crystal display, including a first step of preparing a plasma generating apparatus that uses a working gas to generate plasma, wherein the plasma generating apparatus includes a metal electrode of a sheet shape that is powered by a power supply unit, a substrate located on the metal electrode, an upper magnet that is located on the substrate at a distance of over an average free path length of electrons and forms the direction of a magnetic field oriented toward the substrate at a constant tilt angle, and a lower magnet located below the metal electrode so that the lower magnet has the same magnetic field direction as the upper magnet, wherein the lower magnet is connected to the power supply unit connected to the metal electrode, whereby the lower magnet is powered by the power supply unit to generate plasma; a second step of forming a thin film transistor on the substrate; a third step of forming a DLC thin film on the thin film transistor; and a fourth step of providing the substrate in which the ITO electrode is formed to the plasma generating apparatus that is prepared in the first step, supplying a gas in which H₂ and Ar gas are mixed with C₂H₂ or CH₄ gas to the plasma generating apparatus, and locating the substrate at a given angle between 0 to 90° to form a DLC thin film on the substrate, thereby directly forming a DLC liquid crystal alignment film.

According to a sixteenth aspect of the present invention, there is provided an atmospheric pressure plasma generating apparatus, including a first electrode having one ore more curves; and a second electrode disposed opposite to the first electrode and having one or more curves, wherein a predetermined power supply unit applies power to the second electrode and a working gas is supplied between the first electrode and the second electrode to generate plasma.

### BRIEF DESCRIPTION OF THE DRAWINGS

Further objects and advantages of the invention can be more fully understood from the following detailed description taken in conjunction with the accompanying drawings in which:

FIG. 1 is a cross-sectional view showing a plasma generating apparatus according to a first embodiment of the present invention;

FIG. 2 is a perspective view showing a plasma generating head portion of FIG. 1;

FIG. 3 shows the configuration of a plasma generating apparatus according to a second embodiment of the present invention;

FIG. 4 shows the configuration of a plasma generating apparatus according to a third embodiment of the present invention;

FIG. 5 is a cross-sectional view and a perspective view showing a first discharge metal electrode of FIG. 4;

FIG. 6 shows the configuration of a plasma generating apparatus according to a fourth embodiment of the present invention;

FIG. 7 shows the configuration of a plasma generating apparatus according to a fifth embodiment of the present invention;

FIG. 8 shows a basic power supply circuit of the plasma generating apparatus according to the present invention;

FIG. 9 shows the configuration of a vacuum plasma generating apparatus for forming a liquid crystal display alignment film;

FIG. 10 shows the configuration of a plasma generating apparatus according to a sixth embodiment of the present invention;

FIG. 11 shows the configuration of first and second electrodes of the plasma generating apparatus shown in FIG. 10;

FIG. 12 is a cross-sectional views of the plasma generating apparatus taken along lines AA-AAA in FIG. 10 in order to show the flow rate of a working gas;

FIG. 13 is a cross-sectional views of the plasma generating apparatus taken along lines BB-BBB in FIG. 10 in order to show the flow rate of a working gas;

FIG. 14 is a cross-sectional view showing a plasma generating apparatus according to a seventh embodiment of the present invention;

FIG. 15 shows the configuration of a single power supply unit that is used in the plasma generating apparatus according to the present invention;

FIG. 16 shows the configuration of a power supply unit including an independent bias power that is used in the plasma generating apparatus according to the present invention;

FIG. 17 is a photograph (50,000 magnifications) showing variations in the surface of polyimide depending upon a plasma surface processing time of a nitrogen gas;

FIG. 18 is a photograph (50,000 magnifications) showing variations in the polyimide surface depending upon a plasma surface processing time of air gas; and

FIG. 19 is a graph showing a variation in contact angle on the surface of polyimide depending upon a plasma surface processing time.

### DETAILED DESCRIPTION OF THE PREFERRED EMBODIMENT

A plasma generating apparatus of the present invention has a structure in which a main electrode generates plasma of a high density having directivity, wherein the main electrode that can generate a high non-uniform electric field is disposed within a magnetic field having constant directivity and the main electrode is applied with a high voltage to generate plasma having directivity.

As an embodiment, a sharp blade electrode of a blade shape is attached to the main electrode. A magnet is located at the back of the blade electrode and a first discharge electrode is located next to the main electrode. A working gas is supplied between the main electrode and the first discharge electrode, the main electrode and the first discharge electrode are powered by a power supply unit to generate a first discharge plasma, and plasma is supplied to the blade electrode to which a high voltage is applied to generate a main plasma by means of a high non-uniform electric field of the blade electrode. Thus, long plasma having directivity is generated by the magnet at the back of the blade electrode. The surface of polyimide of a LCD undergoes the plasma at a given angle, or the surface of ITO (Indium Tin Oxide) of a LCD is processed or a thin alignment film of the DLC is formed by the plasma.

Formation of the alignment film of the DLC has the following advantages. In a post-process of the LCD at a high temperature, reliability of the post-process can be secured since the DLC alignment film is thermally stable unlike polyimide. Productivity can be improved because the process is continuous to pre- and post-process. According to the present invention, many processes such as coating of polyimide, sintering at high temperature, rubbing, cleaning and dry can be omitted. A mask process can be also omitted.

Currently, main structure and processes of the LCD includes forming ITO as a transparent electrode on an active element thin film transistor (TFT), spin-coating polyimide on the ITO, rubbing polyimide for liquid crystal alignment directivity to form an alignment film, and supplying liquid crystal to the surface of the alignment film so that the liquid crystal is aligned in a predetermined direction. The alignment direction of the liquid crystal varies depending upon the direction of rubbing. For a wide view angle, the liquid crystal is rubbed in various directions to form multi domains.

The present invention can be applied to a liquid crystal display process as follows: (1) to replace an existing process in which polyimide is rubbed using a roller with a plasma processing process of the present invention, (2) to form a DLC thin film instead of existing polyimide and to replace it with the plasma processing process of the present invention, (3) to directly fabricate an alignment thin film of a DLC having directivity using a plasma apparatus of the present invention instead of existing polyimide, and (4) to directly form an alignment film without polyimide or a DLC thin film while improving electrical conductivity by processing the surface of ITO of a transparent electrode using plasma of the present invention.

The present invention will now be described in detail in connection with preferred embodiments with reference to the accompanying drawings.

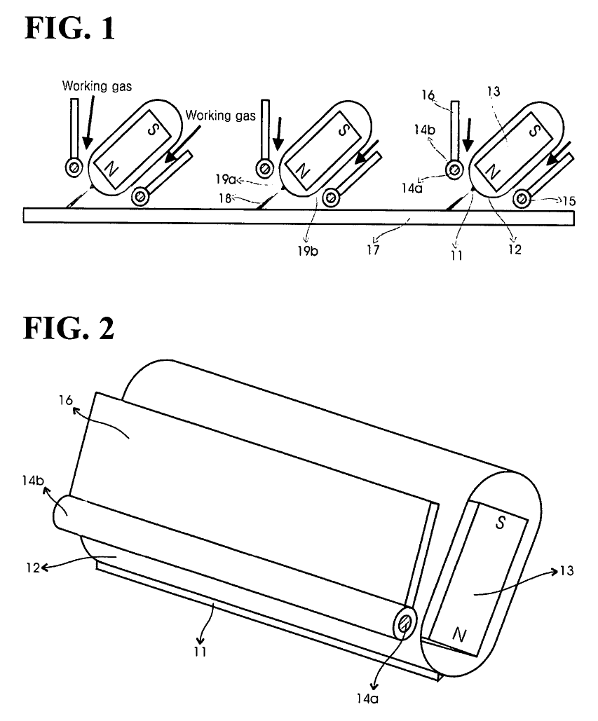

FIG. 1 is a cross-sectional view showing a plasma generating apparatus according to a first embodiment of the present invention. FIG. 2 is a perspective view showing a plasma generating head portion having a magnet, a main electrode, a blade electrode, a first discharge electrode and a working gas guide plate. FIG. 8 shows a basic power supply circuit in the plasma generating apparatus according to the present invention.

Referring to FIGS. 1, 2 and 8, a high voltage is applied from an AC or DC main power HV2 of FIG. 8 to a main electrode 12 of FIG. 1. At least one blade electrode 11 is disposed beneath the bottom of the main electrode 12. A first discharge electrode 14a of a rod shape is located next to the main electrode 12. The first discharge electrode 14a is surrounded by a dielectric material 14b and a magnet 13 is disposed at the back of the blade electrodes 11. The magnet 13 can be located within the main electrode 12 or at the back of the main electrode 12.

A working gas guide plate 16 is located at the back of the first discharge electrode 14a with it spaced apart from the main electrode 12 by a certain distance. A working gas is supplied between the working gas guide plate 16 and the main electrode 12 and a high AC voltage of a first discharge power HV1 is applied between the main electrode 12 and the first discharge electrode 14a to generate a first plasma 19a, so that ions, electrons and free radicals are supplied to the blade electrodes 11.

The blade electrodes 11 generates a main plasma 18 of a high density by means of a high non-uniform electric field effect and a sample 17 located opposite to the blade electrodes 11 is processed by means of the generated main plasma.

Main features of the present invention will now be described.

Generally, if a high voltage is applied to a metal electrode having a sharp edge, plasma is generated by means of a high non-uniform electric field effect. In this time, the plasma is called corona discharging. In the case of this corona discharging, electrons are approximately below 10¹⁰#/cm¹ and the current is below 10⁻² mA. Thus, very weak plasma is formed and its applications are thus limited.

In the present invention, in order to increase the density of plasma, a first plasma 19 is generated by the first discharge electrode 14a and lots of ions, electrons, free radicals, etc. are thus supplied to the blade electrodes 11, so that plasma of an electron density (10¹⁰ to 10¹⁴ #cm³) higher than a glow discharge level is generated. The magnet 13 disposed at the back of the blade electrodes 11 makes the plasma have directivity so that plasma is not generated in unnecessary surrounding spaces. The magnet 13 also serves to significantly increase the length of plasma generated so that the plasma can process materials of a three-dimensional shape. That is, the magnet 13 serves to allow the directivity and to increase the length of plasma generated, which are important in surface processing.

FIG. 1 shows an embodiment in which one or more plasma generating heads are used and a material to be processed (sample) is processed by plasma having directivity of a given angle at a predetermined angle. In this drawing, two first discharge electrodes are used in one main electrode. FIG. 2 is a perspective view of a plasma generating head portion, which can process a large-area surface using a long blade electrode 11.

A working gas used to generate this plasma may include at least one of argon, helium, air, nitrogen, oxygen, steam, methane, acetylene, hydrogen, a metal organic material, an organic material, fluorine based gas and the like. The pressure of the working gas used is set to 10⁻¹⁰ to 1520 Torr.

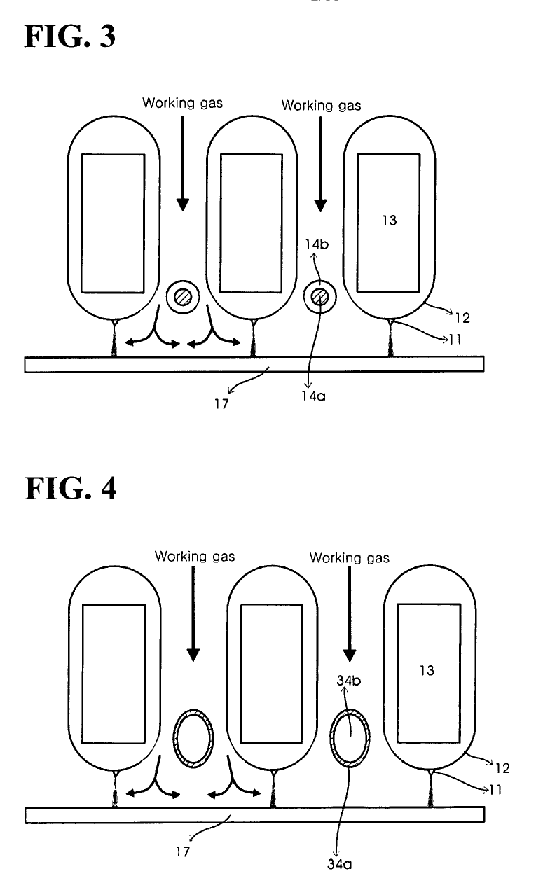

In FIG. 3, the aforementioned plasma generating heads are used one or more and one first discharge electrode is located between two main electrodes. First discharge plasma is thus generated between the first discharge electrode and the two main electrodes. In this time, the plasma heads are disposed in a vertical manner to a material (a sample) to be processed so that plasma having vertical directivity is generated.

FIG. 4 shows an example in which the structure of the first discharge electrode includes a line electrode 34a. In FIG. 4, reference numeral 34b indicates an insulator such as a dielectric material.

This employs the principle of a plasma generating apparatus that is disclosed in Korean Patent Application No. 10-2003-7091, which was invented and applied by the same applicant as that of the present invention. As described above, if plasma is obtained using the line electrode, more strong first discharge plasma can be obtained. If this first discharge plasma is used, more strong main plasma can be obtained.

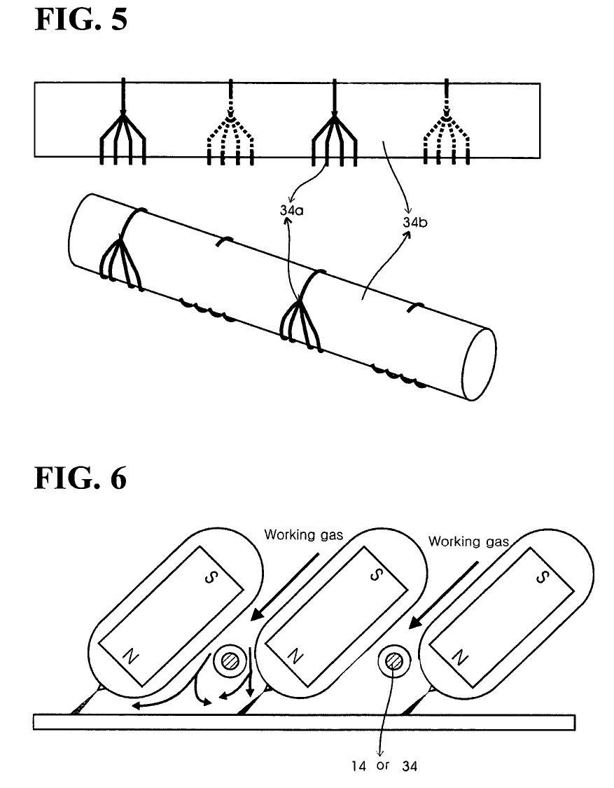

FIG. 5 is a cross-sectional view and a perspective view showing a first discharge metal electrode composed of the line electrode 34a. One or more line electrodes are constructed in branch shape so that plasma is generated along respective line branch electrodes.

FIG. 6 shows an embodiment in which the plasma head of FIG. 3 and FIG. 4 is constructed to have a given tilt angle from a material (a sample) to be processed to provide slant plasma.

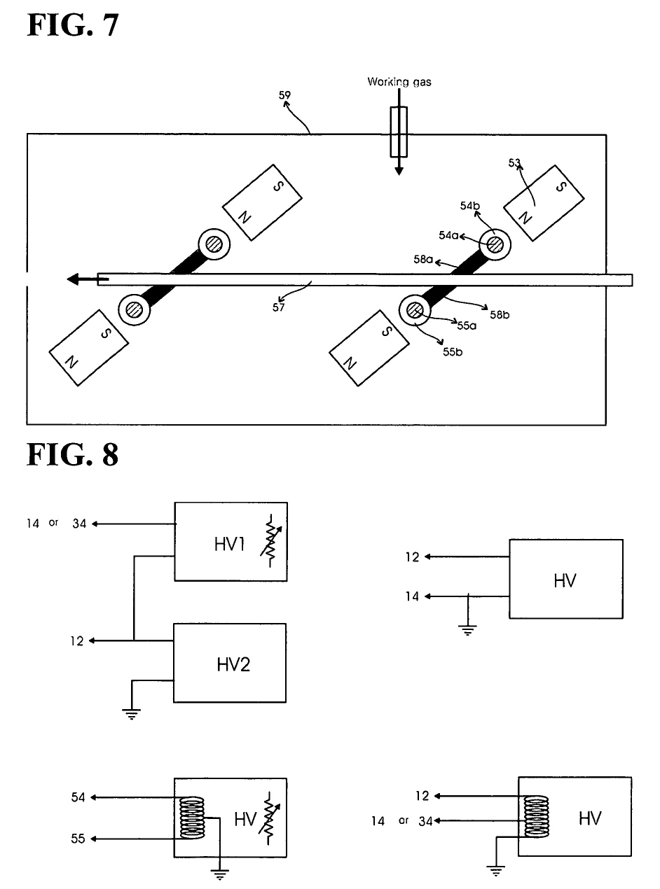

FIG. 7 shows the configuration of a plasma generating apparatus according to a fifth embodiment of the present invention. In FIG. 7, a main electrode of a rod shape (also called rod electrode) is used. An upper electrode 54a is surrounded by a dielectric rod 54b and a magnet 53 is located over the upper rod electrode 54 at a given angle.

The magnet 53 is located over the upper rod electrode 54 and a magnet is located under a lower rod electrode 55 so that the direction of a magnetic field is oriented toward the straight-line direction where the upper rod electrode 54 and the lower rod electrode 55 face each other.

In this time, a substrate (or a sample) 57 is located between the upper rod electrode 54 and the lower rod electrode 55. The lower rod electrode 55 is located at a location parallel to the magnetic field so that plasma is generated in the magnetic field direction and directivity is thus given.

The plasma generating apparatus shown in FIG. 7 is different from the plasma generating method of the existing dielectric rod shape in that the magnet 53 is located at the back of the upper and lower rod electrodes 54 and 55 so that the locations of the upper and lower electrodes form a given angle and are located parallel to the magnetic field direction. By doing so, it is possible to form plasma having directivity.

At this time, the dielectric electrode method of the rod shape shown in FIG. 7 is advantageous in that a sample can be processed in short time because a plasma processing area of one plasma head is wide compared to those of the blade electrode method, but is disadvantageous in that materials of a 3-dimensional shape can be processed.

The plasma 18 generated from the blade electrodes shown in FIG. 2 has a blade edge line shape. The shape of the plasma is illuminated to the sample and an area where the plasma is processed is thus small. On the contrary, in FIG. 7, plasma of a size corresponding to the diameter of the rod electrode 54a is generated (assuming that their lengths are same). The area of plasma illuminated to the sample is thus great.

Further, in the structure of the electrode type of FIG. 7, the upper rod electrode 54, the sample 57 and the lower rod electrode 55 are sequentially disposed and plasma is generated by applying a high voltage between the upper rod electrode and the lower rod electrode. In this time, a distance between the upper and lower rod electrodes cannot be made large. Therefore, a thickness of a sample that is inserted between the upper and lower rod electrodes is limited and its applications are limited to samples of a three-dimensional structure. Accordingly, the apparatus shown in FIG. 5 can be advantageously used for a material (a sample) of a thin sheet shape.

FIG. 8 shows a basic power supply circuit of the plasma generating apparatus according to the present invention. The basic power supply circuit employs DC or AC of a high voltage. In the present invention, a main plasma is generated and a frequency of a first discharge power supply unit employs an AC or DC voltage of a sine wave, a square wave, a saw tooth wave, etc. of 0 Hz to 900 MHz.

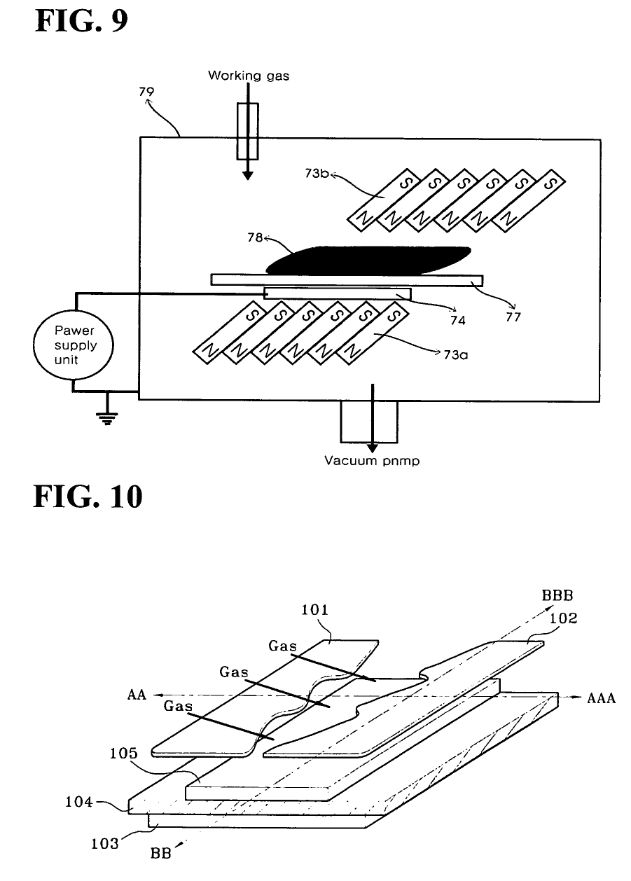

FIG. 9 shows a vacuum plasma generating apparatus for forming an alignment film of a liquid crystal display. Magnets 73a are disposed so that they are oriented toward a sample 77 at a constant angle. A metal electrode 74 of a sheet shape is located between the magnets 73a and the sample 77 and is connected to a power supply unit. Magnets 73b are located at a place that is spaced apart from the sample by a certain distance (it refers to a distance that is needed to secure a space where plasma is generated and also refers to over an average free path distance of electrons depending on the degree of vacuum) so that uniform magnetic field directivity is formed from the surface of the sample and plasma energy generated can be thus transferred to the sample at a given angle.

In FIG. 9, a working gas is supplied at the degree of vacuum of 10⁻² Torr that can be exhausted by a rotary pump. A proper working pressure is approximately 1 to 50 Torr. This is a pressure that can be obtained even using one rotary pump and has an advantage compared to a common vacuum apparatus. Further, a large area and high density plasma can be easily obtained and processing efficiency is high since directivity higher than atmospheric pressure plasma can be secured. In FIG. 9, reference numeral 74 indicates a main electrode.

If magnets are used in an existing sputtering apparatus, the direction of a magnetic field is generally disposed parallel to the surface of an electrode. In the present invention, however, the magnets are disposed at a given angle to the surface of the electrode to secure directivity of plasma. Power is applied to a main electrode and a ground electrode is connected to a chamber body. At this time, plasma is generated around the main electrode.

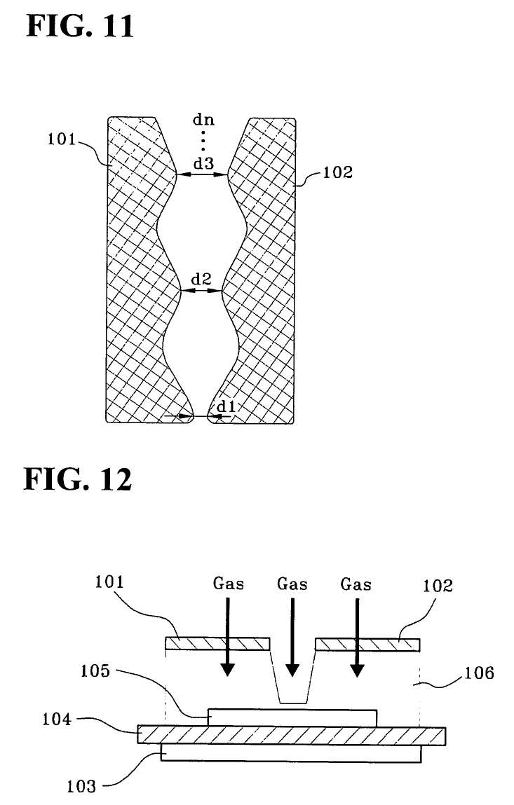

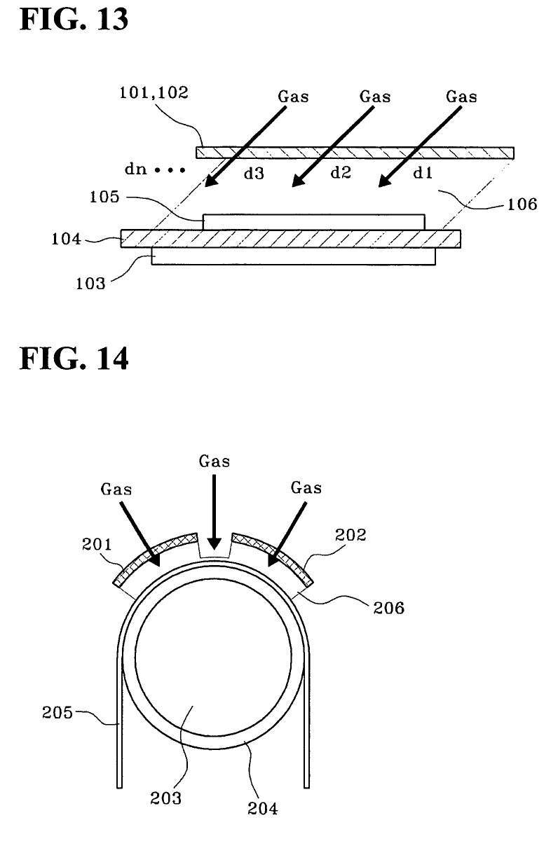

FIG. 10 shows the configuration of a plasma generating apparatus according to a sixth embodiment of the present invention. FIG. 11 shows the configuration of first and second electrodes in the plasma generating apparatus shown in FIG. 10. FIG. 12 is a cross-sectional views of the plasma generating apparatus taken along lines AA-AAA in FIG. 10 in order to show the flow rate of a working gas. FIG. 13 is a cross-sectional views of the plasma generating apparatus taken along lines BB-BBB in FIG. 10 in order to show the flow rate of a working gas.

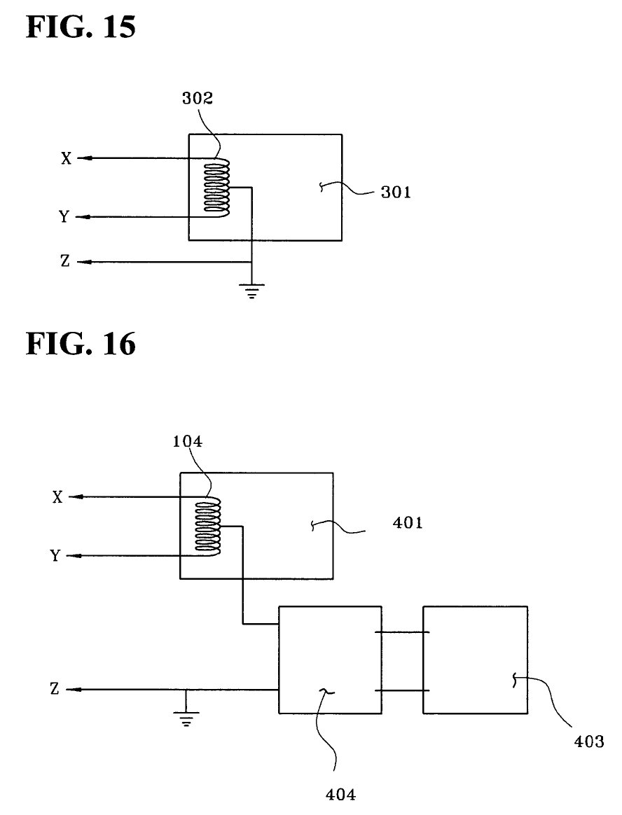

Further, FIG. 14 is a cross-sectional view showing a plasma generating apparatus according to a seventh embodiment of the present invention. FIG. 15 shows the configuration of a single power supply unit used in the plasma generating apparatus according to the present invention. FIG. 16 shows the configuration of a power supply unit including an independent bias power that is used in the plasma generating apparatus according to the present invention.

The atmospheric pressure plasma generating apparatus of the present invention will now be described with reference to the accompanying drawings.

Referring to FIG. 10, a first electrode 101 and a second electrode 102 of a netting thread or plate shape are provided. In this time, a current limiting AC or DC voltage that is indicated by X in FIG. 15 or FIG. 16 is applied to the first electrode 101. A current limiting AC or DC voltage that is indicated by Y in FIG. 15 or FIG. 16 is applied to the second electrode 102.

The first electrode 101 and the second electrode 102 will now be described in detail with reference to FIG. 11. Lines that face each other in the first electrode 101 and the second electrode 102 have curves. In this time, d1 indicates the nearest distance between the electrodes 101 and 102. It is required that the distances indicated in FIG. 11 keep the relationship of d1<d2≦d3≦ . . . ≦dn.

A working gas is flowed between the first electrode 101 and the second electrode 102 while being oriented toward the electrodes at a given angle as in FIG. 12 and FIG. 13, thus inducing plasma 106 to be generated downwardly. At this time, all kinds of gases can be used as the working.

Further, a sample 105 is located under the first electrode 101 and the second electrode 102. A dielectric material 104 is located below the sample 105. A bias electrode 103 is located below the dielectric material 104.

The operation of the plasma generating apparatus constructed above according to an embodiment of the present invention will now be described.

If AC or DC of a high voltage is applied to the first electrode 101 and the second electrode 102 in a state where the working gas is flowed, streamer plasma is generated at the shortest distance d1. The streamer plasma induces plasma to occur along the curves of the first electrode 101 and the second electrode 102 by means of the flow of the working gas. That is, plasma is formed even at a distance of over d2 where plasma is usually not generated.

At this time, if the working gas flows at a constant angle as in FIG. 12 and FIG. 13 and Z of FIG. 15 or FIG. 16 is connected to the bias electrode 103 to apply bias power thereto, generated plasma is easily induced by an electric field formed between the first electrode 101 and the bias electrode 103 and between the second electrode 102 and the bias electrode 103, so that plasma 106 is thus formed as in FIGS. 12 and 13. The density and uniformity of the plasma 106 formed thus are affected by the flow direction and intensity of the working gas, power applied to the first electrode 101 and the second electrode 102, a voltage of a bias power, a distance and so on.

Plasma is formed at a distance where plasma is usually not generated, i.e., a distance between the upper electrodes of the first electrode 101 and the second electrode 102 and the bias electrode 103 in the above structure. Thus, plasma of a more great volume can be formed and a sample of a proper three-dimensional structure can be processed. For detailed information on the principle that plasma is generated that is related to the present invention, please refer to Korean Patent Application No. 10-2003-0007091, which was filed by the applicant of the present invention.

Meanwhile, FIG. 14 is a detailed view when a sample 205 of a roll type is processed. A first electrode 201 and a second electrode 202 having a curvature radius have a structure of a constant curvature in order to make the same shape as the structure of rolls (see reference numerals 203 and 204). Also, the first electrode 201 and a second electrode 202 have a structure having a bias electrode 203 of a cylindrical shape and a dielectric material 204 that surrounds the bias electrode 203.

The operation of the plasma generating apparatus shown in FIG. 14 is the same as the above. Thus, description on it will be omitted in order to avoid redundancy.

Meanwhile, FIG. 15 shows the configuration of a single power supply unit that is used in the atmospheric pressure plasma generating apparatus according to the present invention. A center tap is connected to the bias electrodes 103 and 203 by means of a power supply unit 301 and a high voltage transformer 302 having a center tap, so that a bias potential is produced.

Furthermore, FIG. 16 shows the configuration of a power supply unit including an independent bias power that is used in the plasma generating apparatus according to the present invention. A center tap of a high voltage transformer 402 is connected to an AC or DC bias power supply unit 403 through an EMI filter 404 so that a bias voltage can be applied independently. The EMI filter 404 serves to prevent overload and the leakage current due to interference between a power supply unit 401 and the bias power supply unit 403. The EMI filter 404 consists of a high pass filter or a low pass filter.

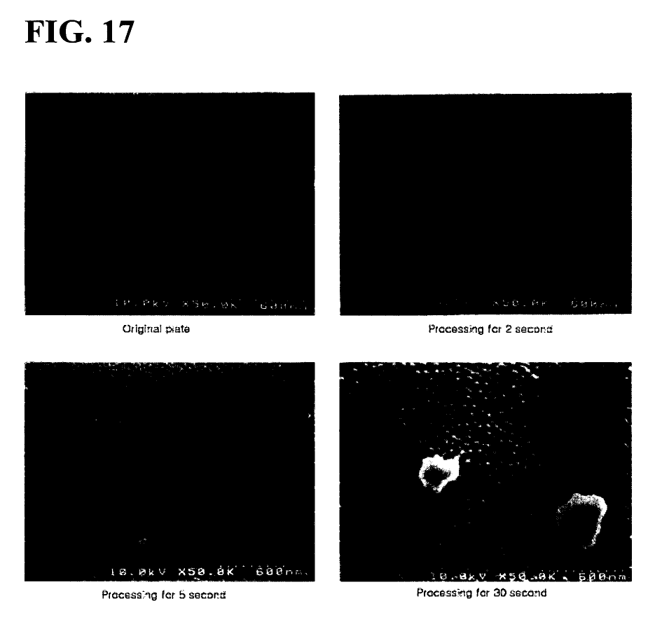

FIG. 17 is an exaggerated photograph (50,000 magnifications) of the surface of polyimide at an atmospheric pressure in order to form an alignment film of a LCD. From FIG. 17, it can be seen that the size of particles is approximately 60 mm after 30 seconds as intensity of illumination of the surface increases uniformly according to a plasma process time. Large particles that are processed for 30 seconds indicate that an impurity as dust is adsorbed to the particles after the processing.

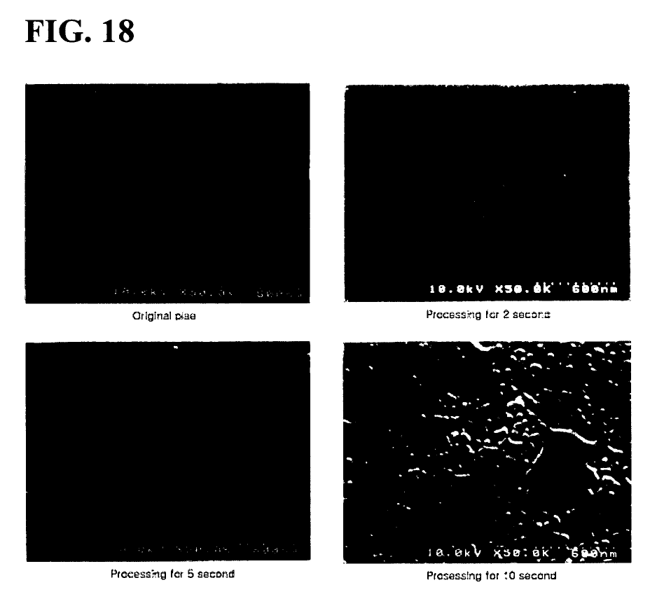

FIG. 18 shows the surface of atmospheric pressure plasma at an air gas atmosphere. From FIG. 18, it can be seen that a large intensity of illumination is obtained even through processing with less time compared to a nitrogen gas shown in FIG. 17. That is, it is considered that oxygen in the air influences the surface of polyimide by more high activation and reactivity.

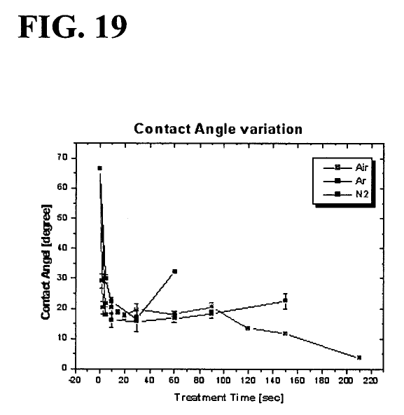

FIG. 19 shows a contact angle that is measured in order to analyze surface energy of polyimide that is processed by atmospheric pressure plasma under various gas atmospheres. In FIG. 19, contact angle data up to 60 seconds indicate an argon gas atmosphere, contact angle data up to 210 seconds indicate air atmosphere, and contact angle data up to 150 seconds indicate an N₂ atmosphere. From FIG. 19, it can be seen that the surface contact angle rapidly decreases after plasma processing.

That is, it indicates that surface energy increases, which indicates that a material of liquid crystal, etc. can be well adsorbed or absorbed. It can be seen that in the case of an argon gas, a contact angle increases again. It can be seen that there is a proper processing condition.

An exact mechanism that liquid crystal is oriented on the surface of rubbed polyimide in a liquid crystal display has not yet been defined. It is roughly expected that the mechanism is generated by a groove effect, etc.

A current process of using polyimide includes spin-coating polyimide in an expensive clean room, curing it in an electric furnace at high temperature of 200 rubbing the surface of polyimide using a roller for alignment, and performing processes such as cleaning and dry and an discontinuous process in order to remove scraps such as debris. Thus, the process has limited productivity, yield, etc.

In order to solve the problems, however, the present invention proposes that a LCD thin film is deposited to fabricate an alignment film using a plasma generating apparatus of the present invention instead of using polyimide. According to the present invention, the alignment film can be formed even through simple processes in which a gas where methane or acetylene gas are mixed with hydrogen gas and argon gas is supplied to the plasma generating apparatus as a working gas and an ITO glass substrate of a LCD is processed with plasma under an atmospheric pressure.

Further, in a LCD process for forming the DLC thin film instead of existing polyimide, it is possible to replace the formed DLC thin flmm with the plasma treatment process of the present invention.

If the surface of transparent electrode ITO formed in the LCD process is processed by plasma of the present invention, the alignment film can be formed directly without polyimide or a DLC thin film while improving the electrical conductivity.

Moreover, the DLC thin film can be formed under the working gas atmosphere by allowing the plasma generating apparatus to generate atmospheric pressure plasma. The DLC thin film having directivity is thus fabricated by plasma having directivity. Thus, liquid crystal can be oriented in a given direction on the DLC thin film without additional process.

Therefore, the present invention has the following advantages. By simply using a blade electrode and a first discharge electrode as described above, a structure is simplified and time and manpower taken for maintenance are reduced. Durability is also high and large-area plasma can be generated. Surface reforming and cleaning are possible for any materials such as metal, semiconductor, plastic and ceramics regardless of the kind of a sample as well as a complex 3-D sample. In forming an alignment film of a LCD, technologies for forming an alignment film of the surface of polyimide and forming an alignment film of a LCD can significantly reduce existing processes by means of the plasma generating apparatus and can be performed continuously. Therefore, the yield is increased, the unit cost is lowered, the quality of DLC image is significantly improved, and high quality fabrication is possible.

As described above, according to the present invention, a large-area plasma generating apparatus that can be commercialized can be fabricated with simple structure and low cost through the use of simple blade electrodes and a first discharge electrode. Time and manpower taken for maintenance can be saved and durability is also high. Surface reforming and cleaning are possible for any materials such as metal, semiconductor, plastic and ceramics regardless of the kind of a sample as well as a complex 3-D sample. Thus, various substrate processing conditions can be satisfied technologies for forming an alignment film of the surface of polyimide and forming an alignment film of a DLC can significantly reduce existing processes by means of the plasma generating apparatus and can be performed continuously. Further, the yield is increase, the unit cost is lowered and the quality of LCD image is significantly improved.

Further, the present invention has effects that the structure is simple, time and manpower taken for maintenance are reduced and durability is high since netting thread or plate shape electrode pairs and a bias electrode simply having a curve are used.

Also, efficiency is high since a working gas flow control system is used and the structure is simple. A plasma generating apparatus of a large area that can be commercialized can be fabricated with low cost.

In addition, surface reforming and cleaning are possible for any materials such as metal, semiconductor, plastic and ceramics regardless of the kind of a sample as well as a complex 3-D sample. Thus, various plasma types, e.g., normal glow plasma, abnormal glow plasma, etc. can be obtained by simply changing the direction and flow rate of a working gas and a voltage. Accordingly, the present invention has an effect that various substrate process conditions can be satisfied.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

1. A plasma generating apparatus that generates a main plasma using a discharge phenomenon that is caused by a high non-uniform electric field in a main electrode by a voltage supplied between a ground electrode and the main electrode from a power supply unit, and a working gas, comprising:
discharge electrodes that are spaced apart by a certain distance from one side of the main electrode that is applied with voltage to generate the main plasma;
at least one blade electrode disposed beneath the bottom of the main electrode; and
a magnet located at the back of the blade electrodes, for generating a magnetic field that gives directivity to the generated main plasma,
wherein a predetermined power supply unit supplies power to the main electrode and the discharge electrodes, and the working gas is supplied between the main electrode and the discharge electrodes to thereby generate discharge plasma preferentially.

2. The plasma generating apparatus as claimed in claim 1, wherein the blade electrodes and the direction of the magnetic field of the magnet are oriented toward the substrate at a constant tilt angle.

3. The plasma generating apparatus as claimed in claim 1, wherein an outer edge and end of the main electrode have a shape that is not angled and has a given curvature.

4. The plasma generating apparatus as claimed in claim 1, wherein the working gas uses one of air, steam (H₂O), oxygen (O₂), nitrogen (N₂), hydrogen (H₂), argon (Ar), helium (He), xenon (Xe), methane (CH₄), ammonia (NH₃), CF₄, acetylene (C₂H₂), propane (C₃H₈), a metal organic material, an organic material, an inorganic material and a fluorine based gas, or a mixture of two or more thereof.

5. The plasma generating apparatus as claimed in claim 1, wherein the pressure of the working gas is set to 10⁻¹⁰ to 1520 Torr.

6. A plasma generating apparatus, comprising:
a dielectric upper electrode of a rod shape;
a first magnet disposed over the dielectric upper electrode;
a substrate disposed below the dielectric upper electrode;
a dielectric lower electrode of a rod shape that is disposed below the substrate; and
a second magnet disposed under the dielectric lower electrode, wherein a predetermined power supply unit applies power between the upper and lower electrodes of the rod shape to generate plasma.

7. The plasma generating apparatus as claimed in claim 6, wherein the dielectric electrodes of the rod shape and the direction of a magnetic field of the magnets are oriented toward the substrate at a constant tilt angle.

8. A plasma generating apparatus that uses a working gas to generate plasma, comprising:
a metal electrode of a sheet shape that is powered by a power supply unit;
a sample located on the metal electrode;
an upper magnet that is located over the sample at a distance of over an average free path length of electrons and forms the direction of a magnetic field oriented toward the sample at a constant tilt angle; and
a lower magnet located below the metal electrode so that the lower magnet has the same magnetic field direction as the upper magnet, wherein the lower magnet is connected to the power supply unit connected to the metal electrode, whereby the lower magnet is powered by the power supply unit to generate plasma.

9. A method of forming an alignment film of a liquid crystal display, comprising:
a first step of preparing a plasma generating apparatus that generates a main plasma using a discharge phenomenon that is caused by a high non-uniform electric field at a main electrode by a voltage supplied between a ground electrode and the main electrode from a power supply unit and a working gas wherein discharge electrodes are spaced apart by a certain distance from the side of the main electrode, a voltage is supplied to the main electrode and the discharge electrodes and the working gas is supplied between the main electrode and the discharge electrodes to generate discharge plasma, at least one blade electrode is disposed beneath the main electrode, and a magnet is located at the back of the blade electrode to generate a magnetic field that gives directivity to the main plasma;
a second step of forming a thin film transistor on the substrate;
a third step of forming an ITO electrode on the thin film transistor;
a fourth step of forming either a polyimide film or a DLC thin film on the ITO electrode; and
a fifth step of providing the substrate in which either the polyimide film or the DLC thin film is formed to the plasma generating apparatus that is prepared in the first step, and processing the surface of either the polyimide film or the DLC thin film of the substrate using the plasma generated by the plasma generating apparatus.

10. The method as claimed in claim 9, wherein the surface processing time is set to 1 second to 30 minutes.

11. A method of forming an alignment film of a liquid crystal display, comprising:
a first step of preparing a plasma generating apparatus, wherein the plasma generating apparatus includes a dielectric upper electrode of a rod shape, a first magnet disposed over the dielectric upper electrode, a substrate disposed below the dielectric upper electrode, a dielectric lower electrode of a rod shape that is disposed below the substrate, and a second magnet disposed under the dielectric lower electrode, wherein a predetermined power supply unit applies power between the upper and lower electrodes of the rod shape to generate plasma;
a second step of forming a thin film transistor on the substrate;
a third step of forming an ITO electrode on the thin film transistor;
a fourth step of forming either a polyimide film or a DLC thin film on the ITO electrode; and
a fifth step of providing the substrate in which either the polyimide film or the DLC thin film is formed to the plasma generating apparatus that is prepared in the first step, and processing the surface of either the polyimide film or the DLC thin film of the substrate using the plasma generated by the plasma generating apparatus.

12. A method of forming an alignment film of a liquid crystal display, comprising:
a first step of preparing a plasma generating apparatus that uses a working gas to generate plasma, wherein the plasma generating apparatus includes a metal electrode of a sheet shape that is powered by a power supply unit, a substrate located on the metal electrode, an upper magnet that is located on the substrate at a distance of over an average free path length of electrons and forms the direction of a magnetic field oriented toward the substrate at a constant tilt angle, and a lower magnet located below the metal electrode so that the lower magnet has the same magnetic field direction as the upper magnet, wherein the lower magnet is connected to the power supply unit connected to the metal electrode, whereby the lower magnet is powered by the power supply unit to generate plasma;
a second step of forming a thin film transistor on the substrate;
a third step of forming an ITO electrode on the thin film transistor;
a fourth step of forming either a polyimide film or a DLC thin film on the ITO electrode; and
a fifth step of providing the substrate in which either the polyimide film or the DLC thin film is formed to the plasma generating apparatus that is prepared in the first step, and processing the surface of either the polyimide film or the DLC thin film of the substrate using the plasma generated by the plasma generating apparatus.

13. An atmospheric pressure plasma generating apparatus, comprising:
a first electrode having one ore more curves; and
a second electrode disposed opposite to the first electrode and having one or more curves, wherein a predetermined power supply unit applies power to the second electrode and a working gas is supplied between the first electrode and the second electrode to generate plasma.

14. The atmospheric pressure plasma generating apparatus as claimed in claim 13, wherein the first electrode and the second electrode have a netting thread, plate or line structure.

15. The atmospheric pressure plasma generating apparatus as claimed in claim 13, wherein the direction of the working gas is oriented toward the faces of the first and second electrodes at a constant angle.

16. The atmospheric pressure plasma generating apparatus as claimed in claim 13, wherein a bias electrode is located below the first and second electrodes and connected to a center tap of the power supply unit.

17. The atmospheric pressure plasma generating apparatus as claimed in claim 13, further comprising a given controller for controlling the flow of the working gas.
